(19) United States
(12) Patent Application Publication
(10) Pub. No.: US 2025/0174773 A1
(43) Pub. Date: May 29, 2025

(54) TEMPERATURE-SENSITIVE HOUSING FOR A BATTERY CELL

(71) Applicant: SAMSUNG SDI CO., LTD., Yongin-si (KR)

(72) Inventor: Eymen IPEK, Graz (AT)

(21) Appl. No.: 18/882,232

(22) Filed: Sep. 11, 2024

(30) Foreign Application Priority Data
Nov. 28, 2023 (EP) 23212795.1

(51) Int. Cl. H01M 50/124; G01R 31/364; H01M 10/48; H01M 50/103; H01M 50/119; H01M 50/128

(52) U.S. Cl. CPC H01M 50/1245; G01R 31/364; H01M 10/488; H01M 50/103; H01M 50/119; H01M 50/128; H01M 2220/20

(57) ABSTRACT

The present disclosure refers to a temperature-sensitive housing for a battery cell, a battery module having the battery cell accommodated in the temperature-sensitive housing, a battery system using the battery module, a vehicle including the temperature-sensitive housing, the battery module, or the battery system, and a method for detecting a thermal event occurring in the battery cell equipped with the temperature-sensitive housing. The temperature-sensitive housing includes a case having an outer surface, and a coating at least partially covering the outer surface of the case, and including a temperature-sensitive material having a temperature-dependent electrical resistance.

### CROSS-REFERENCE TO RELATED APPLICATION

The present application claims priority to and the benefit of European Patent Application No. 23212795.1, filed on Nov. 28, 2023, in the European Patent Office, the entire disclosure of which is incorporated herein by reference.

### BACKGROUND

### 1. Field

The present disclosure relates to a temperature-sensitive housing for a battery cell.

### 2. Description of the Related Art

Recently, vehicles for transportation of goods and peoples have been developed that use electric power as a source for motion. Such an electric vehicle is an automobile that is propelled by an electric motor by using energy stored in rechargeable batteries. An electric vehicle may be solely powered by batteries, or may be hybrid vehicle powered by, for example, a gasoline generator or a hydrogen fuel power cell. A hybrid vehicle may include a combination of an electric motor and conventional combustion engine. Generally, an electric-vehicle battery, (EVB, or traction battery) is a battery used to power the propulsion of battery electric vehicles, (BEVs). Electric-vehicle batteries differ from starting, lighting, and ignition batteries in that they are designed to provide power for sustained periods of time.

A rechargeable (or secondary) battery differs from a primary battery in that it is designed to be repeatedly charged and discharged, while the latter is designed to provide only an irreversible conversion of chemical to electrical energy. Low-capacity rechargeable batteries are used as power supplies for small electronic devices, such as cellular phones, notebook computers, and camcorders, while high-capacity rechargeable batteries are used as power supplies for electric and hybrid vehicles and the like.

Generally, rechargeable batteries include an electrode assembly including a positive electrode, a negative electrode, and a separator interposed between the positive and negative electrodes, a case receiving the electrode assembly, and an electrode terminal electrically connected to the electrode assembly. An electrolyte solution is injected into the case to enable charging and discharging of the battery via an electrochemical reaction of the positive electrode, the negative electrode, and the electrolyte solution. The shape of the case, such as cylindrical or rectangular, may be selected based on the battery's intended purpose. Lithium-ion (and similar lithium polymer) batteries, widely known FOR their use in laptops and consumer electronics, dominate the most recent electric vehicles in development.

### SUMMARY

The present disclosure is related to a battery module having several battery cells accommodated in a temperature-sensitive housing. Also, the present disclosure is related to a battery system using the battery module, the battery system allowing for an accurate monitoring of the temperature state of the battery cells. Moreover, the present disclosure relates to a method for detecting a thermal event occurring in a battery cell equipped with a temperature-sensitive housing.

The present disclosure is defined by the appended claims, with functional equivalents thereof to be included therein. The description that follows is subjected to this limitation. Any disclosure lying outside the scope of said claims is only intended for illustrative as well as comparative purposes.

According to a first aspect of the present disclosure, a temperature-sensitive housing for a battery cell, the temperature-sensitive housing including a case having an outer surface, and a coating at least partially covering the outer surface of the case, and including a temperature-sensitive material having a temperature-dependent electrical resistance.

The case may include a substrate material as a substrate for the coating, the substrate material including aluminum or an alloy including aluminum.

The coating may include an insulating layer including an electrically insulating material on the substrate material.

The insulating layer may include an aluminum oxide layer.

The insulating layer may include aluminum oxide and may have a thickness of about 0.05 μm or more.

The coating may include a temperature-sensitive layer including the temperature-sensitive material.

The temperature-sensitive layer may directly contact the insulating layer.

The temperature-sensitive layer may include TiOₓ/Cr₂O₃.

The temperature-sensitive layer may cover most of the outer surface of the case.

The temperature-sensitive layer may include one or more stripes on the outer surface of the case.

According to a second aspect of the present disclosure, a battery module includes the battery cell including the temperature-sensitive housing.

The battery module may further include one or more ohmmeters, and one or more electric circuits including a first measurement terminal and a second measurement terminal, wherein the temperature-sensitive housing is integrated into at least one of the electric circuits, and wherein the ohmmeters are configured to measure an electrical resistance between the first measurement terminal and the second measurement terminal of at least one of the electric circuits.

According to a third aspect of the present disclosure, a battery system includes the battery module, and an evaluation unit configured to receive signals from the ohmmeters indicating the electrical resistance, detect a deviance of the signals from a setpoint value assigned to the ohmmeters, and generate an alert signal upon the deviance exceeding a threshold.

According to a fourth aspect of the present disclosure, a vehicle including the temperature-sensitive housing, the battery module, and/or the battery system.

According to a fourth aspect of the present disclosure, a method for detecting a thermal event occurring in the battery cell equipped with the temperature-sensitive housing includes providing a first electric conduit and a second electric conduit electrically connected at different respective positions to the temperature-sensitive material of the temperature-sensitive housing, measuring, by ohmmeters, an electrical resistance between the first electric conduit and the second electric conduit, creating, by the ohmmeters, a signal indicating the electrical resistance, transferring the signal to an evaluation unit, evaluating, by the evaluation unit and based on the signal, a deviation of the electrical resistance from a setpoint value, and generating an alert signal upon the deviation exceeding a threshold.

Further aspects of the present disclosure could be learned from the following description.

### BRIEF DESCRIPTION OF THE DRAWINGS

Aspects will become apparent to those of ordinary skill in the art by describing in detail embodiments with reference to the attached drawings in which:

FIG. 1 is a perspective view illustrating a typical design of a battery cell according to the state-of-the-art.

FIG. 2 is a schematic longitudinal cut through one or more embodiments of a battery cell housing according to one or more embodiments of the present disclosure.

FIG. 3 provides a schematic perspective view of a battery cell housing according to one or more other embodiments of the present disclosure.

FIG. 4 provides a schematic side view of a battery cell housing according to still one or more other embodiments of the present disclosure.

FIG. 5 is a cross-sectional image showing the microstructure of an example of a coating that can be used in embodiments of a case of a housing according to one or more embodiments of the present disclosure.

FIG. 6 is a diagram illustrating the dependency of the electric resistance of a TiO₂/Cr₂O₃ layer on the average temperature T_{average} of the TiO₂/Cr₂O₃ layer.

FIGS. 7A, 7B, and 7C illustrate various embodiments of a battery module according to an aspect of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a schematic cross-sectional view” means when a schematic cross-section taken by vertically cutting an object portion is viewed from the side. The terms “face” and “facing” may mean that a first object may directly or indirectly oppose a second object. If a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only when the portion is “directly beneath” another portion but also when there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices, such as field programmable gate arrays (FPGAs).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Rechargeable batteries may be used as a battery module formed of a plurality of battery cells coupled to each other in series and/or in parallel to provide high energy density, such as for motor driving of a hybrid vehicle. For example, the battery module may be formed by interconnecting the electrode terminals of the plurality of unit battery cells in an arrangement or configuration depending on a desired amount of power to realize a high-power rechargeable battery.

Battery modules can be constructed in either a block design or a modular design. In the block design, each battery is coupled to a common current collector structure, and a common battery management system and the unit thereof is arranged in a housing. In the modular design, pluralities of battery cells are connected together to form submodules, and several submodules are connected together to form the battery module. In automotive applications, battery systems generally include a plurality of battery modules connected in series for providing a desired voltage. The battery modules may include submodules with a plurality of stacked battery cells, and each stack includes cells connected in parallel that are, in turn, connected in series (XpYs), or includes cells connected in series that are, in turn, connected in parallel (XsYp).

A battery pack is a set of any number of (usually substantially identical) battery modules. The battery modules may be configured in series, in parallel, or a mixture of both to deliver the desired voltage, capacity, and/or power density. Components of a battery pack include the individual battery modules and the interconnects, which provide electrical conductivity between the battery modules.

A battery system may also include a battery management system (BMS), which is any suitable electronic system that is configured to manage the rechargeable battery, battery module, and battery pack, such as by protecting the batteries from operating beyond their safe operating area, to monitor their states, to calculate secondary data, to report that data, to control its environment, and to authenticate it and/or balance it. For example, the BMS may monitor the state of the battery as represented by voltage (e.g., a total voltage of the battery pack or of the battery modules, and/or voltages of individual cells), temperature (e.g., an average temperature of the battery pack or of the battery modules, a coolant intake temperature, a coolant output temperature, and/or temperatures of individual cells), coolant flow (e.g., flow rate and/or cooling liquid pressure), and current. The BMS may calculate values based on the above parameters, such as minimum and maximum cell voltage, state of charge (SOC) or depth of discharge (DOD) to indicate the charge level of the battery, state of health (SOH, a variously-defined measurement of the remaining capacity of the battery as a percentage of the original capacity), state of power (SOP, the amount of power available for a defined time interval given the current power usage, temperature, and other conditions), state of safety (SOS), maximum charge current as a charge current limit (CCL), maximum discharge current as a discharge current limit (DCL), and internal impedance of a cell (to determine open circuit voltage).

The BMS may be centralized such that a single controller is connected to the battery cells through a multitude of wires. In other examples, the BMS may be distributed, with a BMS board installed at each cell, and with just a single communication cable between the battery and a controller. In yet other examples, the BMS may have a modular construction including a few controllers, each controller handling a certain number of cells, while allowing for communication between the controllers. Centralized BMSs may be most economical, but also may be least expandable, and may suffer from a multitude of wires. Distributed BMSs may be the most expensive, but also may be simplest to install while offering the cleanest/simplest assembly. Modular BMSs may provide a compromise of the features and problems of the other two topologies.

A BMS may protect the battery pack from operating outside its safe operating area. Operation outside the safe operating area may be indicated by over-current, over-voltage (during charging), over-temperature, under-temperature, over-pressure, and ground fault or leakage current detection. The BMS may reduce or prevent the likelihood of the battery operating outside its safe operating parameter by including an internal switch (e.g., a relay or solid-state device) that opens if the battery operates outside its safe operating parameters, and by requesting the devices to which the battery is connected to reduce or even terminate using the battery, and also by actively controlling the environment, such as through heaters, fans, air conditioning, and/or liquid cooling.

Static control of battery power output and charging may not be sufficient to meet the dynamic power desirability of various electrical consumers connected to the battery system. Steady exchange of information between the battery system and the controllers of the electrical consumers may be employed. This information may include the battery system's actual state of charge (SoC), potential electrical performance, charging ability, internal resistance, as well as actual or predicted power desirability or power surpluses of the consumers. Battery systems may include a battery management system (BMS) for obtaining and processing such information on a system level, and may also include a plurality of battery module managers (BMMs), which are part of the system's battery modules, and which obtain and process relevant information on a module level. The BMS may measure the system voltage, the system current, the local temperature at respective places inside the system housing, and the insulation resistance between live components and the system housing while the BMMs usually measure the individual cell voltages and temperatures of the battery cells in a battery module.

The BMS/BMU may be provided to manage the battery pack, such as by protecting the battery from operating outside its safe operating area (or safe operating parameters), by monitoring its state, by calculating secondary data, by reporting that data, by controlling its environment, by authenticating it, and/or by balancing it.

In an abnormal operation state (or in the event of an abnormal condition), a battery pack may be disconnected from a load connected to a terminal of the battery pack. Battery systems may include a battery disconnect unit (BDU) that is electrically connected between the battery module and battery system terminals. The BDU may be the primary interface between the battery pack and the electrical system of the vehicle. The BDU may include electromechanical switches that open or close high current paths between the battery pack and the electrical system. The BDU provides feedback to the battery control unit (BCU), accompanied to the battery modules, such as voltage and current measurements. The BCU controls the switches in the BDU by using low current paths based on the feedback received from the BDU. The primary functions of the BDU may include controlling current flow between the battery pack and the electrical system, and current sensing. The BDU may further manage additional functions, such as external charging and pre-charging.

An active or passive thermal management system may be included to provide thermal control of the battery pack to safely use the at least one battery module by efficiently emitting, discharging, and/or dissipating heat generated from its rechargeable batteries. If the heat emission/discharge/dissipation is not sufficiently performed, temperature deviations may occur between respective battery cells, such that the at least one battery module may no longer generate a desired (or designed) amount of power. An increase of the internal temperature can lead to abnormal reactions occurring therein, and thus charging and discharging performance of the rechargeable battery may deteriorate, and the lifespan of the rechargeable battery may be shortened.

Exothermic decomposition of cell components may lead to a so-called thermal runaway. Generally, thermal runaway describes a process that accelerates due to increased temperature, in turn releasing energy that further increases temperature. Thermal runaway occurs in situations if an increase in temperature changes the conditions in a way that causes a further increase in temperature, often leading to a destructive result. In rechargeable battery systems, thermal runaway is associated with strong exothermic reactions that are accelerated by temperature rise. These exothermic reactions include combustion of flammable gas compositions within the battery pack housing. For example, if a cell is heated above a critical temperature (for example, above about 150° C.) the cell can transition into a thermal runaway. The initial heating may be caused by a local failure, such as a cell internal short circuit, heating from a defective electrical contact, a short circuit to a neighboring cell, etc. During the thermal runaway, a failed battery cell (e.g., a battery cell that has a local failure) may reach a temperature exceeding about 700° C. Further, large quantities of hot gas may be ejected from inside of the failed battery cell through the venting opening of the cell housing into the battery pack. The main components of the vented gas are H₂, CO₂, CO, electrolyte vapor, and other hydrocarbons. The vented gas may be flammable and potentially toxic. The vented gas also causes a gas-pressure to increase inside the battery pack.

As described before, automotive battery systems have battery cells that can be hazardous in the event of a failure. Passengers may be warned before any danger occurs outside of the battery. Fast detection of cell failures may be desired.

There is a desire for a device and a method that allow for an accurate monitoring of the temperature states of the battery cells used in a battery module battery system, for example, if configured to be used in fully electric or hybrid vehicles. Further, there is a desire for a device and a method that allow for giving a fast alert in a serious thermal event, such as a thermal run-away occurring in one or more of the battery cells. Also, monitoring the temperature of battery cells may be desirable to manage battery lifetime.

An aspect of the present disclosure provides a device and a method that allow for an accurate monitoring of the temperature states of battery cells used in a battery module. Further, an aspect of the present disclosure provides a device and a method that allow for giving a fast alert in the event of a serious thermal event, such as a thermal run-away occurring in one or more of the battery cells.

The housing for a battery cell can be structured in a way that the resistance of the housing is changing with the temperature of the battery cell accommodated in the housing. This can improve the accuracy of temperature measurement of cells.

Measuring and/or monitoring the temperature of battery cells (e.g., even the temperature of individual battery cells) may be desirable to manage battery lifetime. Fast thermal runaway detection may be done if the individual cell temperature is known. Whether a battery cell housing material can act like a positive/negative temperature coefficient resistor can be detected by using a battery management system.

According to a first aspect of the present disclosure, a temperature-sensitive housing for a battery cell is provided, the temperature-sensitive housing including a case having an outer surface, and a coating that at least partially covers the outer surface of the case, and that includes a temperature-sensitive material having a temperature-dependent electrical resistance.

The term “temperature-sensitive housing” is used herein to simply distinguish the housing according to the present disclosure from common housings. In one or more embodiments, the housing according to the present disclosure could be simply referred to as “housing” or “housing according to the present disclosure.”

Further, the term “temperature-sensitive material” is used herein to simply distinguish a material with a temperature-dependent measurable characteristic (e.g., the electrical resistance) from other materials. A term, such as “first material” or “special material” could have been used instead of “temperature-sensitive material.” The “first material” or “special material” may be defined herein as a material with a temperature-dependent electrical resistance.

The first aspect of the present disclosure may be summarized as follows. The battery cell housing may be structured by using a temperature-dependent resistive material. The housing may provide the following aspect. If the housing is connected to an (external) signal-conditioning circuit, the signal-conditioning circuit can detect a change in the temperature of the battery cell housing by measuring resistance of the cell housing.

There are different metallic and composite based materials that may be used as coating for battery cell housing. The electrical resistance of these materials may change significantly (e.g., by a factor of about 1000), for example in a temperature range between about 80° C. to about 300° C., which may be a typical failure temperature range for battery cells. The temperature-sensitive housing according to the first aspect uses such materials, coatings, or thin films to detect changes in the temperature-dependent resistance.

For example, the battery cell may be suitable for powering an electric vehicle, or for being employed in a battery module for powering an electric vehicle, in a battery system for powering an electric vehicle, or in a battery pack for powering an electric vehicle. Electric vehicle may refer to, for example, a fully electric vehicle or a hybrid vehicle (see above).

The case may have a prismatic shape. For example, the case may have a cuboid shape.

The coating may be arranged on one or more regions of the outer surface of the case. In one or more embodiments, the coating may be arranged on an entirety of the outer surface of the case. The case may have a plurality of essentially planar outer side faces. The coating may be arranged on one or more regions of at least one outer side face. In one or more embodiments, the coating may be arranged on an entirety of the surface of at least one outer side face.

In one or more embodiments of the temperature-sensitive housing, the case may be made of a substrate material forming a substrate for the coating. For example, the substrate material may include aluminum, or may include an alloy including aluminum, or may include a material including aluminum.

The term “substrate material” is used simply to label this material by its purpose to provide a substrate for the coating. A term, such as “second material” could be used instead of “substrate material.”

In embodiments, the coating may include at least two layers. For example, the coating may contain only two layers, or the coating may contain three layers.

In one or more embodiments of the temperature-sensitive housing, the coating includes an insulating layer made of an electrically insulating material, wherein the insulating layer is arranged on the substrate material.

The term “insulating layer” is used simply to label this layer by its characteristic of including an electrically insulating material. A term, such as “first layer” may be used instead of “insulating layer.”

In embodiments, the insulating layer directly contacts the substrate material.

In one or more embodiments of the temperature-sensitive housing, the insulating layer is an aluminum oxide layer.

In embodiments, wherein the case is made of aluminum, the aluminum oxide (Al₂O₃) layer is the natural aluminum oxide forming on the surface of the aluminum case due to spontaneous reaction of the aluminum material with oxygen of ambient air. This “natural” passivating aluminum oxide layer may be about 0.05 μm thick. In one or more embodiments, aluminum oxide layers with a thickness of about 5 μm or thicker can be produced, (e.g., by electrical oxidation (anodizing) or by chemical means).

Al₂O₃ is an electrical insulator. For example, an aluminum oxide layer produced by anodizing is a good electrical insulator with breakdown strengths of about 900 V at an anodized layer thickness of about 30 μm. Moreover, Al₂O₃ has a relatively high thermal conductivity (e.g., around 30 Wm⁻¹K⁻¹) for a ceramic material.

In embodiments of the temperature-sensitive housing using a case made of aluminum, an alloy including aluminum, or a material including aluminum, the insulating layer may not have to be applied to the outer surface of the aluminum case (e.g., by anodizing), but may be formed by itself (“naturally”) by a reaction of the outer surface of the case with the oxygen included in the ambient air.

In one or more embodiments of the temperature-sensitive housing, the insulating layer may be, or may include aluminum oxide. The insulating layer may have a thickness of more than about 0.05 μm, for example a thickness of more than about 5 μm. For example, the insulating layer may have a thickness of more than about 10 μm. The insulating layer may have a thickness of more than about 50 μm. For example, the insulating layer may have a thickness of more than about 100 μm.

In such embodiments, the insulating layer may be an aluminum oxide layer with a thickness larger than the thickness of an aluminum oxide layer, which may form naturally (see above) by spontaneous reaction of the aluminum included in the case with the oxygen of the ambient air. Technical methods, like electrical oxidation (anodizing) or chemical means, may be employed to apply the insulating layer onto the outer surface of the case in those embodiments.

In one or more embodiments of the temperature-sensitive housing, the coating includes a temperature-sensitive layer, the temperature-sensitive layer being made of the temperature-sensitive material.

The temperature-sensitive layer may be used simply to label this layer by its characteristic of being made of the temperature-sensitive material. A term, such as “second layer” may be used herein instead of “temperature-sensitive layer.” The temperature-sensitive layer may be formed as a film.

In one or more embodiments, the temperature-sensitive housing may include at least one pair of electrodes. Each pair of electrodes including a first electrode and a second electrode, each of the first electrode and second electrode being electrically connected to the temperature-sensitive layer, and being connectable to an (external) electric line or electric conduit. Thereby, the first electrode and the second electrode may be connected to the temperature-sensitive layer at different positions. Then, an electric resistance can be measured between the first electrode and the second electrode. Further, the first electrode and the second electrode may be connected to a contiguous region of the temperature-sensitive layer to ensure that a current can be conducted between the first and second electrode. For example, if the temperature-sensitive layer is arranged as a plurality of separated stripes on the outer surface of the case, the first and second electrode of a pair of electrodes may be connected to the same stripe.

The electrodes may be formed as terminals. Also, the endings of the terminals may be accommodated in a socket configured for being connected to the plug of a cable, or may be accommodated in a plug configured for being connected to the socket of a cable (e.g., an external cable). In such embodiments the connection of the temperature-sensitive housing according to the first aspect of the present disclosure with a measurement device or a BMU or the like may be facilitated.

In one or more embodiments of the temperature-sensitive housing, the temperature-sensitive layer directly contacts the insulating layer. In such embodiments, the insulating layer may be arranged between the case (e.g., the substrate material) and the temperature-sensitive layer. For example, the insulating layer may be sandwiched between the substrate material and the temperature-sensitive layer.

In embodiments, the temperature-sensitive layer may be made of, or may include, a material having a positive temperature coefficient (PTC) with regard to the electrical resistance of the material. In one or more other embodiments, the temperature-sensitive layer may be made of, or may include, a material having a negative temperature coefficient (NTC) with regard to the electrical resistance of the material.

In one or more embodiments of the temperature-sensitive housing, the temperature-sensitive layer is made of a material including TiOₓ/Cr₂O₃ (e.g., TiO₂/Cr₂O₃).

In embodiments, wherein the temperature-sensitive layer is made of TiOₓ/Cr₂O₃, the temperature-sensitive layer may have a negative temperature coefficient (NTC) with regard to its electrical resistance.

In one or more embodiments of the temperature-sensitive housing, the temperature-sensitive layer may cover an entirety of an outer surface of the case, or may cover most of the outer surface of the case.

The temperature-sensitive layer may either directly contact the outer surface of the case or indirectly cover the outer surface of the case. In the latter, the insulating layer may be sandwiched between the case (e.g., the substrate material) and the temperature-sensitive layer. Also, the temperature-sensitive layer may directly cover the substrate material in some regions of the outer surface of the case while only indirectly covering the outer surface of the case.

In one or more embodiments of the temperature-sensitive housing, the temperature-sensitive layer may be formed as one or more stripes arranged on the outer surface of the case.

In one or more embodiments of the temperature-sensitive housing, the coating may include an outer layer covering the outer surface of the case and/or each of the other layers includes in the coating. For example, the outer layer is thereby adapted for electrical insulation and/or mechanical protection.

The term “outer layer” may be used simply to label this layer by its purpose to form the outermost layer of the coating applied to the case's outer surface. A term, such as “third layer” may be used instead of “outer layer.” In embodiments, the outer layer may be a resin layer.

It is remarked that in regions where the outer layer covers one or more of the other layers (e.g., the temperature-sensitive layer and/or the insulating layer), the outer layer may not be in direct contact with the outer surface of the case, because one or more other layers may be sandwiched between the outer surface of the case and the outer layer. Nonetheless, even in such regions where other layer(s) are sandwiched between the outer surface of the case and the outer layer, the outer layer covers the outer surface of the case.

In embodiments, the coating may cover an entirety of the outer surface of the case, or may cover most of the outer surface of the case. In embodiments, each layer of the coating may be arranged in the same region or regions of the outer surface of the case. Then, if the coating includes a temperature-sensitive layer, and an outer layer directly contacting the temperature-sensitive layer, then the outer layer may completely cover the temperature-sensitive layer. Then, if the coating includes an insulating layer and a temperature-sensitive layer directly contacting the insulating layer, the temperature-sensitive layer may completely cover the insulating layer.

In one or more other embodiments, the outer layer may cover more regions of the outer surface of the case than the remaining layers. In regions, where the outer surface of the case is covered by an insulating layer and/or a temperature-sensitive layer, there may be also arranged an outer layer on top of the other layers, while in other regions of the outer surface of the case (e.g., regions not covered by at least one of the insulating layer or the temperature-sensitive layer), the outer layer may directly contact the outer surface of the case.

According to a second aspect of the present disclosure, a battery module is provided, the battery module including at least one battery cell including a temperature-sensitive housing according to one or more of the previously described embodiments (e.g., of the first aspect).

In one or more embodiments, each of the battery cells of the battery modules may be equipped with one or more embodiments of the temperature-sensitive housing according to the first aspect.

In one or more embodiments of the battery module according to the second aspect, the battery module may further include one or more devices (e.g., ohmmeters) for measuring an electrical resistance, and one or more electric circuits each having a first measurement terminal and a second measurement terminal, with one or more of the temperature-sensitive housings being integrated into at least one of the electric circuits. Each of the devices may be adapted to measure the electrical resistance between the first measurement terminal and the second measurement terminal of at least one of the electric circuits.

In embodiments of the battery module, there may be used only a single device for measuring an electric resistance. In one or more other embodiments, there may be used a plurality (e.g., two, three, four, or more) of devices for measuring an electric resistance.

In embodiments of the battery module, at least one of the devices for measuring an electric resistance may be an ohmmeter. In one or more embodiments of the battery module, each of the devices for measuring an electric resistance may be an ohmmeter.

Any one of the temperature-sensitive housings may be integrated into one of the electric circuits such that a contiguous region of its temperature-sensitive material is connected to a first electrical conduit provided by the circuit at a first position, and to a second electrical conduit provided by the circuit at a second position, the first and the second position being spaced apart from each other. Then, upon applying a voltage between the first and second electrical conduit, the temperature-sensitive material causes an electrical resistance between the first and second electrical conduit.

Embodiments of the battery module may include a plurality of temperature-sensitive housings integrated in an electric circuit, wherein all or at least some of the temperature-sensitive housings are connected in series within the circuit.

Embodiments of the battery module may include a plurality of temperature-sensitive housings integrated in an electric circuit, wherein all or at least some of the temperature-sensitive housings are connected in parallel within the circuit.

A third aspect of the present disclosure refers to battery system including at least one battery module (e.g., a battery module according to the second aspect of the disclosure), and an evaluation unit configured for receiving a signal from each of the devices for measuring an electrical resistance, the signal(s) indicating a resistance measured by the respective devices for measuring an electrical resistance. The evaluation unit may also be for detecting a deviance of each of the signals received from a device(s) for measuring an electrical resistance from a setpoint value (e.g., predefined setpoint value) assigned to the respective devices for measuring an electrical resistance, and also may be for generating an alert signal upon detecting a deviance with an absolute value exceeding a threshold (e.g., predefined threshold).

The temperature signal generated by a device(s) for measuring an electrical resistance may be a voltage or a digital signal. The setpoint value may be a value of a resistance, which may correspond to a value or average value of the resistance measured by the respective devices for measuring an electrical resistance if the battery system is in a normal operating state (e.g., is operating without failure). In one or more embodiments, the setpoint value may be adapted to a load connected to the battery system.

The temperature evaluation unit may be integrated in a battery management unit (BMU) or battery management system (BMS) of the battery system or of the device equipped with the battery system.

In embodiments of the battery system, a PTC material may be employed as the temperature-sensitive material of the temperature-sensitive housings. In such embodiments, an alert signal may be generated upon detecting, by one of the devices for measuring a resistance, a resistance (value) exceeding a threshold (e.g., predefined threshold/value) assigned to said devices for measuring a resistance.

In embodiments of the battery system, an NTC material may be employed as the temperature-sensitive material of the temperature-sensitive housings. In such embodiments, an alert signal may be generated upon detecting, by one of the devices for measuring a resistance, a resistance (value) falling below a threshold (e.g., predefined threshold/value) assigned to said devices for measuring a resistance.

The alert signal generated by the battery system may be a voltage that can be measured, or may be a digital signal that can be received by an alert unit (including the apparatus employing the battery system) for generating an alert (e.g., an optical and/or an acoustical signal) that is perceptible by the users of the apparatus employing the battery system (e.g., the driver and/or the passengers of a vehicle with such a battery system). In one or more embodiments, an alert signal generated by the battery system may be an alert (e.g., an optical and/or an acoustical signal) that is perceptible by the users of the apparatus employing the battery system.

A fourth aspect of the present disclosure relates to a vehicle including at least one temperature-sensitive housing (e.g., according to the first aspect), and/or at least one battery module (e.g., according to the second aspect), and/or at least one battery system (e.g., according to the third aspect). The vehicle may be a hybrid vehicle or a fully electric vehicle.

A fifth aspect of the present disclosure deals with a method for detecting a thermal event occurring in a battery cell equipped with a temperature-sensitive housing according to one or more embodiments of the first aspect, the method including the following operations. a) Providing a first electric conduit and a second electric conduit, each of which being electrically connected, at different respective positions, to the temperature-sensitive material of the temperature-sensitive housing, b) measuring, by a device(s) for measuring an electrical resistance, an electrical resistance between the first electric conduit and the second electric conduit, c) creating, by the device(s) for measuring an electrical resistance, a signal indicating the measured electrical resistance, d) transferring the signal to an evaluation unit, e) evaluating, by the evaluation unit, and based on the signal, a deviation of the measured resistance and a setpoint value (e.g., predefined setpoint value), and f) generating an alert signal upon detecting a deviation having an absolute value exceeding a threshold (e.g., predefined threshold). Evaluating a deviation may include a sub-operation of converting the signal received from the device(s) for measuring an electrical resistance into a value.

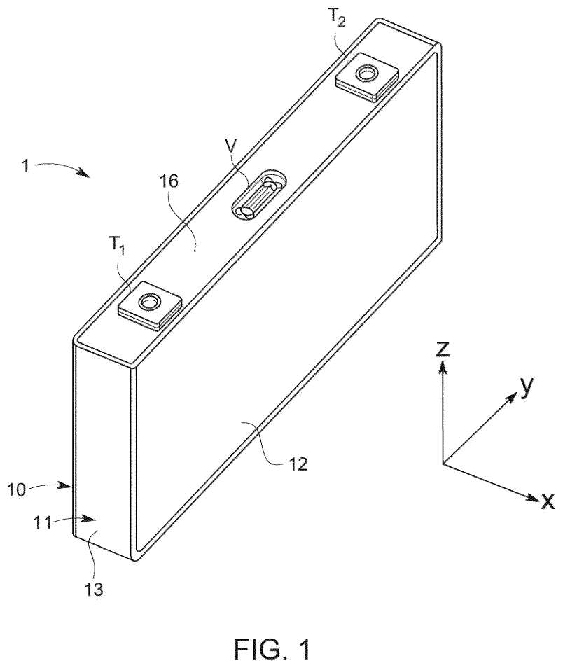

FIG. 1 is a perspective view illustrating a typical design of a battery cell 1 (e.g., used in a battery module for an electric or hybrid vehicle). To facilitate the following description, a Cartesian coordinate system with axes x, y, and z is depicted in FIG. 1. The illustrated battery cell 1 has a prismatic (cuboid) shape essentially defined by a housing 10. For example, the housing 10 is built by a case 11 including six essentially planar side faces. In one or more embodiments, a rear side of the case 11 is arranged perpendicular to the x-axis, and a front side 12 with a shape congruent to the rear side is arranged opposite to the rear side, the front side 12 being likewise perpendicular to the x-axis. Further, in one or more embodiments, the housing 10 includes a first lateral side 13 arranged perpendicular to the y-axis, and a second lateral side with a shape congruent to first lateral side is arranged opposite to the first lateral side 13, the second lateral side being likewise perpendicular to the y-axis. Finally, in one or more embodiments, a bottom side is arranged perpendicular to the z-axis, and an upper side 16 with a shape congruent to the bottom side is arranged opposite to the bottom side, the upper side 16 being likewise perpendicular to the z-axis. In the example, the front side 12 and the rear side have the largest areas compared to the remaining sides of the housing 10.

On the upper side 16 of the housing 10 (e.g., the battery cell's side surface facing the z-direction of the coordinate system), a first cell terminal T₁ and a second cell terminal T₂ are arranged. The first and second cell terminals T₁, T₂ allow for an electrical connection of the battery cell 1. The first cell terminal T₁ may be the negative terminal of the battery cell 1, and the second cell terminal T₂ may be the positive terminal of the battery cell 1. Furthermore, between the first cell terminal T₁ and the second cell terminal T₂, a venting outlet V is arranged on the upper side 16. Accordingly, the upper side 16 may be referred to as the “venting side” of battery cell 1 or its housing 10.

Through the venting outlet V, vent gas can be ejected from the battery cell 1 in the event of a thermal event occurring in the battery cell 1, such as a thermal runaway. In one or more embodiments, inside the battery cell 1, a valve may be installed upstream of the venting outlet, the valve being configured to open if the gas pressure inside the battery cell exceeds a value (e.g., predefined value), and configured to remain in a closed stated otherwise (e.g., if the gas pressure inside the battery cell is below the predefined value). Before being output via the venting outlet V, the vent gas may pass the venting valve arranged inside the battery cell 1.

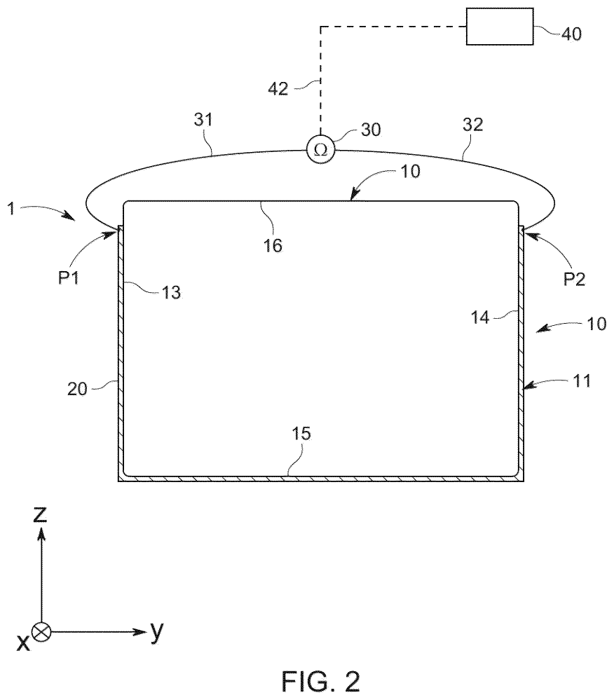

FIG. 2 is a schematic longitudinal cut (parallel to the y-z-plane of the coordinate system) through one or more embodiments of a housing 10 for a battery cell according to the present disclosure. In the example, the overall shape of the housing 10 corresponds to that of the housing 10 as described before with reference to FIG. 1. In one or more embodiments, at least some outer surfaces of side faces of the housing may be covered, or at least partly covered, by a coating 20. The coating 20 may cover outer surfaces of a first lateral side 13 and a second lateral side 14, as well as an outer surface of a bottom side 15 of the housing 10. An upper side 16 of the housing 10 may not be covered by the coating 20, as cell terminals T₁, T₂ and/or a venting outlet V may be arranged on the upper side 16.

In embodiments of the housing according to the present disclosure, at least one of a front side 12 or a rear side may also be covered by the coating 20.

In one or more other embodiments of the housing according to the present disclosure, the front side 12 and the rear side may not be covered by the coating 20. In such embodiments, only the first and second lateral sides 13, 14 and the bottom side 15 may be covered by the coating 20.

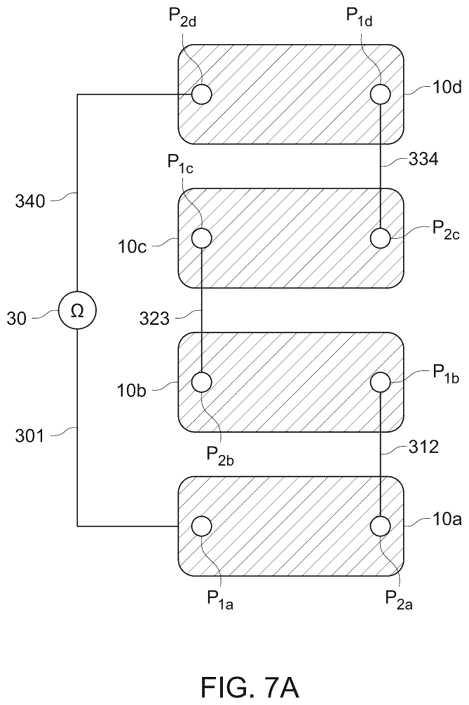

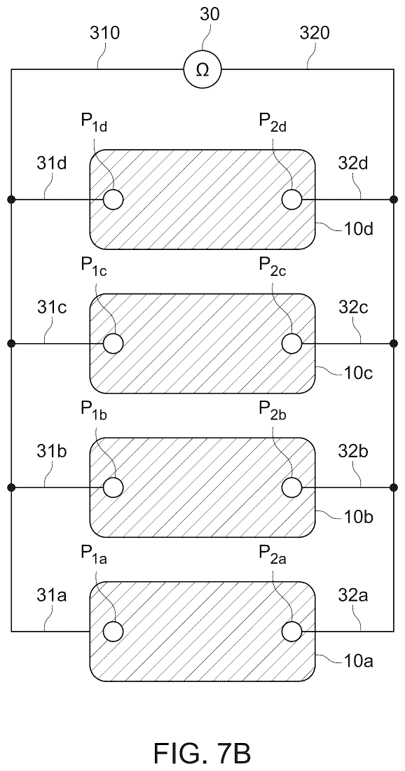

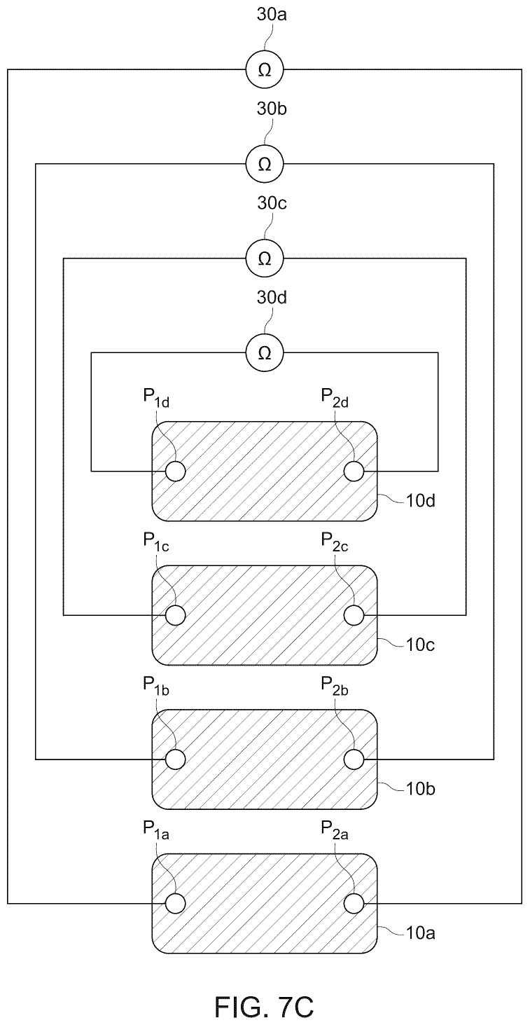

The coating 20 may include a material that exhibits a temperature-dependent electrical resistance, which may be referred to as “temperature-sensitive material.” A resistance can be measured between two different positions on the coating 20. A resistance may be measured between a first position P₁ and a second position P₂, the first position P₁ located in an upper area of the first lateral side 13, and the second position P₂ located in an upper area of the second lateral side 14. An ohmmeter 30 can be used to measure the resistance of the coating 20 between the first and second positions P₁, P₂. The ohmmeter 30 can be connected to the first position P₁ on the coating 20 by a first wire 31 (e.g., wires 31a, 31b, 31c, 31d in FIG. 7B), and can be further connected to the second position P₂ on the coating 20 by a second wire 32 (e.g., wires 32a, 32b, 32c, 32d in FIG. 7B). The ohmmeter 30 may be configured to generate a signal indicative of the measured resistance. The signal may be an analog signal or a digital signal. The signal may be transferred to an evaluation unit 40. To transfer the signal from the ohmmeter 30 to the evaluation unit 40, a signal line 42 (e.g., a cable, a pair of wires, or the like) may be used. In one or more embodiments, the signal may be transferred wirelessly to the evaluation unit 40. Also, the signal may be permanently or periodically transferred to the evaluation unit 40.

Accordingly, if a thermal event (e.g., a thermal runaway) occurs in the battery cell accommodated within the housing 10, the housing 10 may become heated from inside, and the heat may be transferred through the side faces of the housing 10, such that the temperature of the coating 20 may be also increased. Because, as already pointed out above, the coating 20 may include a temperature-sensitive material, the resistance of that material may change as a consequence of this heating process. Depending on the configuration of the temperature-sensitive material, the measured resistance may increase or decrease as the temperature of the coating 20 increases. If the temperature-sensitive material is a material having a positive temperature coefficient (PTC) with regard to its electrical resistance, then the measured resistance increases if the temperature of the coating 20 rises. In one or more embodiments, if the temperature-sensitive material is a material having a negative temperature coefficient (NTC) with regard to its electrical resistance, then the measured resistance decreases if the temperature of the coating 20 rises.

As the evaluation unit 40 may be permanently or periodically fed with a signal indicative of the coating's temperature, the evaluation unit 40 can monitor the temperature of the coating 20, which is in turn indicative of the temperature inside the housing 10 (e.g., the temperature of the battery cell accommodated inside the housing 10). The thermal state of the battery cell accommodated inside the housing 10 can be monitored by the evaluation unit 40.

The evaluation unit 40 may be configured for comparing the measured resistance with a setpoint value (e.g., predefined setpoint value) for the resistance (e.g., a value of the resistance expected to be measured if the battery cell is working correctly). Comparing the measured resistance with the setpoint value (e.g., predefined setpoint value) may include the evaluation unit 40 converting the received signal from the ohmmeter 30 to a value. In embodiments, the comparison may be performed digitally using a CPU. The evaluation unit 40 may include a microcontroller.

If, at a certain point of time t, the measured resistance is denoted by Rₘ(t) and the setpoint value is denoted by R₀, a deviation ΔR may be obtained using the formula ΔR(t):=Rₘ(t)−R₀. Then, if a PTC material is used as the temperature-sensitive material, the evaluation unit 40 may generate an alert if, at a certain point in time t, a deviation ΔR(t) with ΔR(t)>Sₚₒₛ with a threshold (e.g., predefined threshold) Sₚₒₛ is detected, wherein the threshold Sₚₒₛ may be a positive value. In one or more embodiments, the evaluation unit 40 may generate an alert if an average deviation Δ̅R̅(t) with Δ̅R̅(t)>Sₚₒₛ is detected, wherein the average deviation Δ̅R̅(t) is the average of ΔR(T) for all times T in a time interval [t −δt, t] having the duration δt. Thereby, the average can be calculated using an arithmetic mean, a weighted arithmetic mean, a median, a quadratic mean, or any other kind of calculating an average value. The threshold Sₚₒₛ may depend on the electric load, which is powered by the battery cell, and/or on the used temperature-sensitive material, and/or on the geometry of the temperature-sensitive material used in the coating 20, and/or on the positions P₁, P₂.

In one or more embodiments, if an NTC material is used as the temperature-sensitive material, evaluation unit 40 may generate an alert if, at a certain point in time t, a deviation ΔR(t) with ΔR(t)<S_{neg} with a threshold (e.g., predefined threshold) S_{neg} is detected, wherein the threshold S_{neg} may be a negative value. In one or more embodiments, the evaluation unit 40 may generate an alert if an average deviation Δ̅R̅(t) with Δ̅R̅(t)<S_{neg} is detected, wherein the average deviation Δ̅R̅(t) is the average of ΔR(T) for all times T in a time interval [t −δt, t] having the duration St. Thereby, the average can be calculated using an arithmetic mean, a weighted arithmetic mean, a median, a quadratic mean, or any other kind of calculating an average value. The threshold S_{neg} may depend on the electric load, which is powered by the battery cell, and/or on the used temperature-sensitive material, and/or on the geometry of the temperature-sensitive material used in the coating 20, and/or on the positions P₁, P₂.

In one or more embodiments, a positive threshold S may be used irrespectively of using a PTC or an NTC material if an absolute value |ΔR(t)| is used to measure the deviation, instead of only the difference as in the examples above. Then, the evaluation unit 40 may generate an alert if, at a certain point in time t, an absolute deviation |ΔR(t)| with |ΔR(t)|>S with a threshold (e.g., predefined threshold) S>0 is detected. In one or more embodiments, the evaluation unit 40 may generate an alert if an absolute average deviation |Δ̅R̅(t)| with |Δ̅R̅(t)|>S is detected, wherein the absolute average deviation |Δ̅R̅(t)| is the absolute value of the average of ΔR(T) for all times T in a time interval [t−δt, t] having the duration δt. Instead of |Δ̅R̅(t)|>S one may equivalently use ((“ΔR”)⁻“(t)”)²>S² with Δ̅R̅(t) as defined above in the context of using a PCT or NTC material.

In some embodiments of the housing 10, the locations of the first point P₁ and the second point P₂ are such that the distance between these points is large. This is realized by the one or more embodiments corresponding to FIG. 2, because the first and the second point P₁, P₂ are arranged on the first and second lateral sides 13, 14 being opposite to each other with respect to the largest extension of the housing 10 viz. its extension along the y-direction. Choosing a large distance between the first and second points P₁, P₂ has two aspects. First, the measurement of the resistance of the coating 20 becomes more accurate, as incidental local variances of the resistance (e.g., due to variances of the thickness of the coating 20) are averaged out. Second, the measured resistance correlates to an average temperature of a large region of the outer surface of the case accommodating the battery cell, thus allowing for the detection of a thermal event independently of the location within the battery cell, at which the thermal event is strongest or, in the starting phase of the thermal event, independently of the location within the battery cell, at which the thermal event begins.

In the example illustrated in FIG. 2, the resistance becomes only measured with respect to the coating 20 of the housing 10, or, more precisely, with respect to two points P₁, P₂ on the temperature-sensitive material included in the coating 20 of the housing 10. Other embodiments can be used, which will explained in more detail below with reference to FIGS. 7A, 7B, and 7C.

Also, in the example illustrated in FIG. 2, the complete bottom side 15 and at least the major parts of the first and second lateral sides 13, 14 (and, in embodiments, also the front side and the rear side, each of which being not visible in the longitudinal cut of FIG. 2) are covered with the coating 20. In some embodiments of a housing for a battery cell, only parts of one or more side faces of the housing may be covered with a coating.

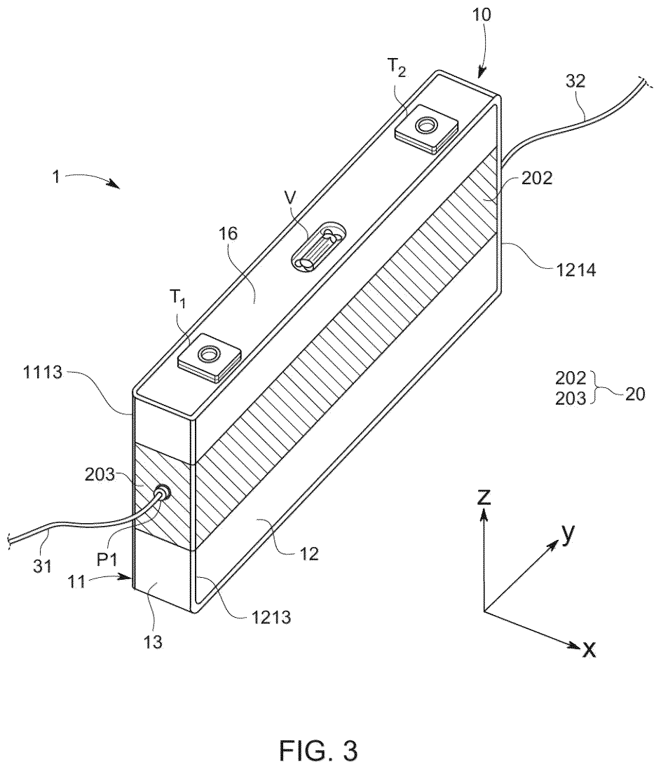

In FIG. 3, a battery cell 1 with a housing 10 is schematically depicted, wherein a coating 20 is formed at least by a stripe 202 arranged in a middle portion (with respect to the z-axis) of a front side 12, and a further stripe 203 arranged in a middle portion (with respect to the z-axis) of a first lateral side 13. In one or more embodiments, further stripes may be arranged in a corresponding way on a rear side and a second lateral side of the housing 10. The stripes 202, 203 forming the coating 20 in the depicted example (and the temperature-sensitive material included in each of the stripes) are electrically connected to each other. The stripe 202 on the front side 12 is linked to the stripe 203 on the first lateral side 13 on a vertical edge 1213 of the housing 10 formed between the front side 12 and the first lateral sides 13. Correspondingly, in one or more embodiments, a stripe on the second lateral side may be linked (e.g., electrically connected) to the stripe 202 on the front side 12 across a vertical edge 1214 between the front side 12 and the second lateral side as well as to a stripe on the rear side across a vertical edge between the second lateral side and the rear side. Eventually, a stripe arranged on the rear side is electrically connected in turn to the stripe 203 arranged on the first lateral side 13.

Then, the resistance of the coating 20 may be measured between the first position P₁ located in a center area of the stripe 203 arranged on the first lateral side 13 and the second position P₂ located correspondingly in a center area of the stripe arranged on the second lateral side. To that end, a first wire 31 is electrically connected to the coating 20 (e.g., to its portion formed by the stripe 203) at the first position P₁ and, correspondingly, a second wire 32 is electrically connected to the coating 20 (e.g., to its portion formed by the stripe arranged on the second lateral side) at the second position P₂. Then, the resistance of the coating between the first and the second positions P₁, P₂ can be measured (e.g., using the ohmmeter 30 correspondingly to the arrangement illustrated in FIG. 2). Also, the evaluation of the measurement and the generation of alerts may be performed similar to that described in the context of FIG. 2.

In one or more embodiments, the resistance may not be measured with regard to an individual housing, but instead with regard to a group of housings, as will be explained below with reference to FIGS. 7A, 7B, and 7C. The first wire 31 and/or the second wire 32 might not be directly connected to the ohmmeter 30, but may instead be connected to one or more further housings similar to that depicted in FIG. 2.

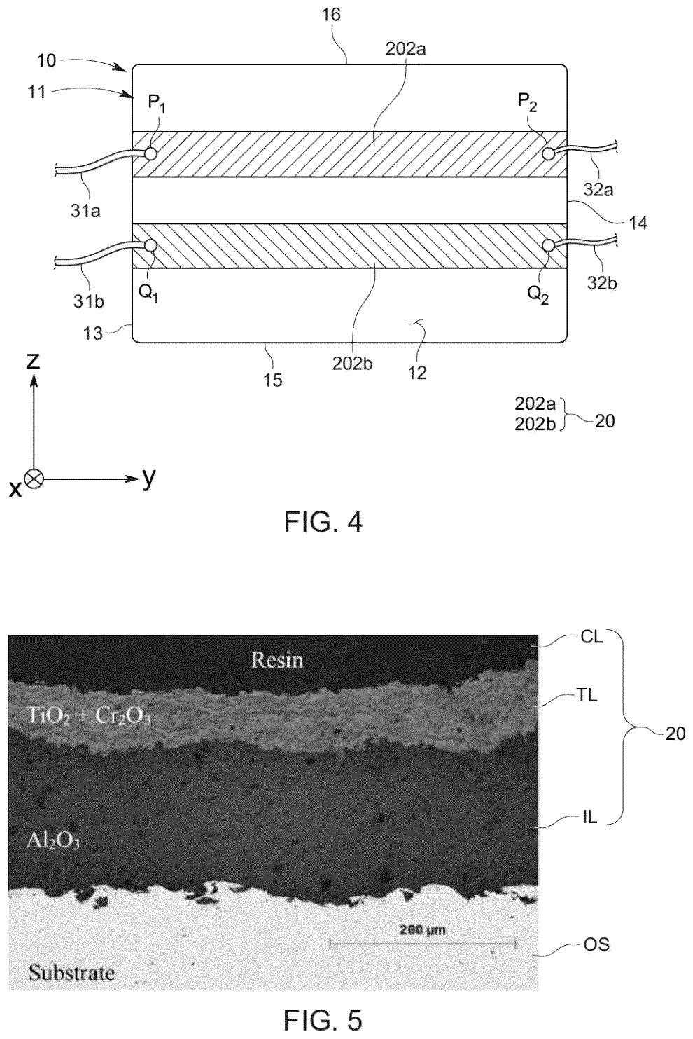

One or more further embodiments of a housing according to the present disclosure is schematically illustrated by FIG. 4 providing a side view onto a housing 10 into the direction against the x-axis of the coordinate system. Again, as in all illustrations herein, the reference signs referring to the side faces of the housing 10 correspond to that introduced with respect to the battery housing of FIG. 1. In the one or more embodiments corresponding to FIG. 4, a coating 20 is formed by two separated stripes being arranged on the front side 12 of the housing 10 (e.g., by an upper stripe 202a and a lower stripe 202b). In this example, the coating 20 is not contiguous, but includes two regions, which are not electrically connected to each other.

Each of the upper stripe 202a and the lower stripe 202b has a certain width with respect to the z-direction, and extends along the y-direction and between the opposite vertical edges of the front side 12 to the first lateral side 13 and of the front side 12 to the second lateral side 14. As to the upper stripe 202a, the resistance may be measured between a first upper point P₁ located on the upper stripe 202a in the vicinity to the first lateral side 13, and a second upper point P₂ located on the upper stripe 202a in the vicinity to the second lateral side 14. Further, as to the lower stripe 202b, the resistance may be measured between a first lower point Q₁ located on the lower stripe 202b in the vicinity to the first lateral side 13, and a second lower point Q₂ located on the lower stripe 202b in the vicinity to the second lateral side 14.

A first upper wire 31a is connected to the first upper point P₁, and a second upper wire 32a is connected to the second upper point P₂. Correspondingly, a first lower wire 31b is connected to the first lower point Q₁, and a second lower wire 32b is connected to the second lower point Q₂. In embodiments, the first upper point P₁ and the second upper point P₂ may be connected to a first ohmmeter to measure a resistance between the first and second upper points P₁, P₂. Also, in one or more embodiments, the first lower point Q₁ and the second lower point Q₂ may be connected to a second ohmmeter to measure a resistance between the first and second lower points Q₁, Q₂.

In one or more embodiments, the first and second upper wires 31a, 32a may be used to connect the upper stripes of each housing of a group of housings according to the housing 10 shown in FIG. 4 within an electric circuit. Correspondingly, the first and second lower wires 31b, 32b may be used to connect the lower stripes of each housing of a group of housings according to the housing 10 shown in FIG. 4 within an electric circuit. For example, in one or more embodiments, by a first electric circuit, the upper stripes of a group of housings according to that depicted in FIG. 4 may be connected in series or connected in parallel. Also, in one or more embodiments, by a second electric circuit, the lower stripes of a group of housings according to that depicted in FIG. 4 may be connected in series or connected in parallel. Then, in one or more embodiments, a first ohmmeter may be configured to measure the overall resistance of the first electric circuit, and a second ohmmeter may be configured to measure the overall resistance of the second electric circuit.

The coating in the region of the upper stripe 202a may be made of the same material, or may be composed identically or similar to the coating in the region of the lower stripe 202b. Then, using the two stripes 202a, 202b may provide redundancy, such that a monitoring of the thermal state of the battery cell accommodated in the housing 10 is still possible even if a deficiency or failure of one of the stripes occurs.

In one or more embodiments, the upper stripe 202a may be made of a material that is different from the material employed in the lower stripe 202b, or the upper stripe 202a may at least be composed differently from the lower stripe 202b. This may improve the accuracy of the temperature-monitoring of the housing 10 over a large interval of temperatures. For example, the upper stripe 202a may include a material having a positive temperature coefficient (PTC) with regard to electrical resistance, and the lower stripe 202b may include a material having a negative temperature coefficient (NTC) with regard to electrical resistance. In one or more embodiments, the upper stripe 202a may include a material having a negative temperature coefficient (NTC) with regard to electrical resistance, and the lower stripe 202b may include a material having a positive temperature coefficient (PTC) with regard to electrical resistance.

In fact, there may be different metallic and composite based materials used in the coating 20 as a temperature-sensitive material. The electrical resistance of these materials may change significantly (e.g., by factor of about 1000), especially in a temperature range between about 80° C. to about 300° C., which is a typical temperature range for failure of battery cells. Different temperature-sensitive materials used in different stripes (in embodiments, even more than two stripes may be used), a large temperature range can be covered at a high accuracy.

Also, in embodiments, the upper and lower stripe may be shaped differently. For example, any one of the upper stripe and the lower stripe can run around the whole housing 10 in a similar way as described before with reference to FIG. 3, while the upper stripe is still separated from the lower stripe. In such embodiments, the first upper and first lower measurement points P₁, Q₁ may each be formed on the first lateral side 13, and the second upper and second lower measurement points P₂, Q₂ may each be formed on the second lateral side 14.

In the embodiments shown in FIGS. 2 to 4, the case 11 of the housing 10 may be made of aluminum. Further, in each of these embodiments, the coating 20 may be composed as described in the following with reference to FIG. 5.

FIG. 5 is a cross-sectional image showing the microstructure of an example of a coating that can be used in embodiments of the case of a housing 10. In such embodiments, the substrate corresponds to a portion of the outer surface OS of the case of a housing 10, and a coating 20 is applied to the substrate, wherein the coating 20 includes three layers IL, TL, CL that will be explained below.

The outer surface OS may be a part of any one of the side faces of the case in a region, where the outer surface of the case is covered by the coating 20 (e.g., in the region of the stripe 202 arranged on the front side 12, referring to FIG. 3). In the example of FIG. 5, the case is made of Aluminum (Al). The coating 20 includes several layers. For example, a layer of an insulating material IL may be arranged directly on the shown portion of the outer surface OS of the case. In the example of FIG. 5, the insulating layer is made of aluminum oxide (Al₂O₃), which is an electrical insulator. If aluminum is exposed to air, an aluminum oxide layer forms naturally aluminum due to spontaneous reaction of the aluminum with the oxygen of the ambient air. The “natural” passivating aluminum oxide layer may be about 0.05 μm thick and may be too small to for a suitable insulating layer. In embodiments of the disclosed housing for a battery cell, relatively thicker aluminum oxide layers may be used (e.g., Al₂O₃ layers with a thickness of at least about 5 μm), which can be produced (e.g., by electrical oxidation (anodizing) or by chemical means).

On the insulating layer IL, a temperature-sensitive layer TL is arranged, which is made of a material having a temperature-dependent electrical resistance. Due to the insulating layer IL sandwiched between the temperature-sensitive layer TL and the outer surface OS of the case, the temperature-sensitive layer TL may be electrically insulated from the case. In the example, the material of the temperature-sensitive layer TL is TiO₂/Cr₂O₃. The TiO₂/Cr₂O₃ layer may be thinner than the Al₂O₃ layer acting as insulating layer IL.

Finally, a closing layer CL may be arranged on the temperature-sensitive layer TL as an outermost layer to protect both, the insulating layer IL and the temperature-sensitive layer TL against undesired mechanical influences, such as impacts, scratches, etc., as well as to provide electrical insulation from external members that may come into mechanical contact with the outer surface of the coating 20. In embodiments, resin may be used as closing layer CL, as shown in the example of FIG. 5.

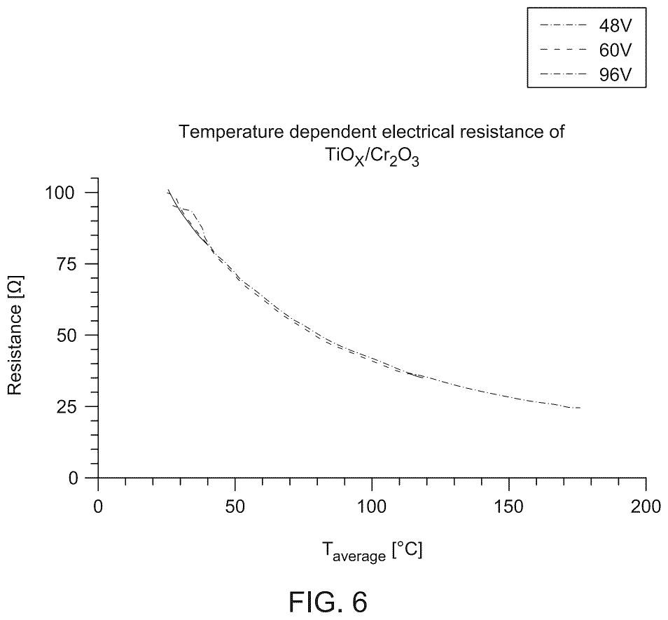

FIG. 6 is a diagram illustrating the electric resistance R(T_{average}) of the TiO₂/Cr₂O₃ layer as a function depending on the average temperature T_{average} of the TiO₂/Cr₂O₃ layer as depicted in FIG. 5. To that end, a voltage can be applied between two points of the layer (e.g., between the first and second points P₁, P₂ as described before with reference to FIGS. 2 to 4) and the resulting current can be measured. Then, the resistance R can be obtained using the Ohm's law R(T_{average})=U/I(T_{average}), with U being the applied voltage and I(T_{average}) denoting the measured current being dependent on the average temperature T_{average} of the TiO₂/Cr₂O₃ layer. The diagram FIG. 6 shows the result of three measurements, using the voltages U=48 V (solid line), U=60 V (dotted line), and U=96 V (dashed line), respectively. During the measurement, the average temperature T_{average} of the TiO₂/Cr₂O₃ layer has been varied in the range between about 25° C. and about 170° C.

Finally, several possibilities of monitoring the temperature state of a group of battery cell housings according to the present disclosure are illustrated in FIGS. 7A, 7B, and 7C. In each of FIGS. 7A, 7B, and 7C, one or more embodiments of a battery module including a stack of four battery cells is shown, each of the battery cells being accommodated in a housing 10a, 10b, 10c, 10d according to the present disclosure. Any one of the shown examples can be easily generalized to battery modules having stacks with a different number of battery cells, for example, stacks having a number of battery cells larger than four. Each of the housings 10a, 10b, 10c, 10d can be designed, for example, like one of the housings depicted in FIG. 2 or FIG. 3. Each of the housings 10a, 10b, 10c, 10d are covered with a coating (indicated here without reference number by the hatching of the shown side faces of the housings, although the coating may not necessarily cover an entirety of the shown side faces). On the coating of each of the housings 10a, 10b, 10c, 10d, a pair of measurement points (P₁ₐ, P₂ₐ), (P_{1b}, P_{2b}), (P_{1c}, P_{2c}), (P_{1d}, P_{2d}) is chosen, respectively.

Between the two points of each of the pairs (P₁ₐ, P₂ₐ), (P_{1b}, P_{2b}), (P_{1c}, P_{2c}), (P_{1d}, P_{2d}), a resistance of the respective coating can be measured. In the following description, for each of the examples shown in FIGS. 7A, 7B, and 7C, the (temperature-dependent) resistance between the first pair (P₁ₐ, P₂ₐ) will be denoted by Rₐ(Tₐ), the (temperature-dependent) resistance between the second pair (P_{1b}, P_{2b}) will be denoted by R_{b}(T_{b}), the (temperature-dependent) resistance between the third pair (P_{1c}, P_{2c}) will be denoted by R_{c}(T_{c}), and the (temperature-dependent) resistance between the fourth pair (P_{1d}, P₂ₐ) will be denoted by R_{d}(T_{d}). The temperatures Tₐ, T_{b}, T_{c}, T_{d} refer to the average temperatures of the coatings of the respective housings 10a, 10b, 10c, 10d between the measurement points of the respective pairs (P₁ₐ, P₂ₐ), (P_{1b}, P_{2b}), (P_{1c}, P_{2c}), (P_{1d}, P_{2d}) of measurement points.

By electric conduits (indicated by the lines) to the measurement points, the housings 10a, 10b, 10c, 10d are integrated into an electric circuit connected to one or more ohmmeters 30, 30a, 30b, 30c, 30d. The arrangement of the components in the electric circuits of the examples shown may differ. These electric circuits may be solely used to monitor the temperature-state of the groups of battery cells, and may be completely independent from circuits used for tapping the voltage generated by the battery cells of the battery modules. The circuits used for tapping the voltage generated by the battery cells of the battery modules may be omitted from FIGS. 7A, 7B, and 7C for the sake of simplicity.

In the one or more embodiments of a battery module corresponding to FIG. 7A, the coatings of the four housings 10a, 10b, 10c, 10d may be connected. For example, a second measurement point P₂ₐ of the first housing 10a is electrically connected to a first measurement point P_{1b} of the second housing 10b by a wire 312, a second measurement point P_{2b} of the second housing 10b is electrically connected to a first measurement point P_{1c} of the third housing 10c by a wire 323, and a second measurement point P_{2c} of the third housing 10c is electrically connected to a first measurement point P_{1d} of the fourth housing 10d by a wire 334. Further, an ohmmeter 30 is connected to a first measurement point P₁ₐ of the first housing 10a by a wire 301, and to a second measurement point P_{2d} of the fourth housing 10d by a wire 340. In one or more embodiments, with the resistances measured for the pairs of measurement points and the temperatures of the coatings of the housings denoted as described above, the ohmmeter 30 is configured to measure an overall resistance R(Tₐ, T_{b}, T_{c}, T_{d})=Rₐ(Tₐ)+R_{b}(T_{b})+R_{c}(T_{c})+R_{d}(T_{d}) in the example of FIG. 7A. If the coatings of each housings 10a, 10b, 10c, 10d include a PTC material, the overall resistance R(Tₐ, T_{b}, T_{c}, T_{d}) may increase if at least one of the temperatures Tₐ, T_{b}, T_{c}, T_{d} increases. In one or more embodiments, if the coatings of each housings 10a, 10b, 10c, 10d include a NTC material (e.g., a TiOₓ/Cr₂O₃ layer as described above with reference to FIG. 5), the overall resistance R(Tₐ, T_{b}, T_{c}, T_{d}) may decrease upon an increase of at least one of the temperatures Tₐ, T_{b}, T_{c}, T_{d}.

In the one or more embodiments of a battery module corresponding to FIG. 7B, the coatings of the four housings 10a, 10b, 10c, 10d are connected in parallel. For example, each of the first measurement points P₁ₐ, P_{1b}, P_{1c}, P_{1d} on the coatings of the respective housings 10a, 10b, 10c, 10d is connected to a first wire 310, and each of the second measurement points P₁ₐ, P_{1b}, P_{1c}, P_{1d} on the coatings of the respective housings 10a, 10b, 10c, 10d is connected to a second wire 320. A ohmmeter 30 is connected to the first wire 310 and the second wire 320. In one or more embodiments, with the resistances measured for the pairs of measurement points and the temperatures of the coatings of the housings denoted as described above, the ohmmeter 30 may be configured to measure an overall resistance R(Tₐ, T_{b}, T_{c}, T_{d})=[1/Rₐ(Tₐ)+1/R_{b}(T_{b})+1/R_{c}(T_{c})+1/R_{d}(T_{d})]⁻¹ in the example of FIG. 7B. If the coatings of each housings 10a, 10b, 10c, 10d include a PTC material, the overall resistance R(Tₐ, T_{b}, T_{c}, T_{d}) will increase if at least one of the temperatures Tₐ, T_{b}, T_{c}, T_{d} increases. In one or more embodiments, if the coatings of each housings 10a, 10b, 10c, 10d include a NTC material (e.g., a TiOₓ/Cr₂O₃ layer as described above with reference to FIG. 5), the overall resistance R(Tₐ, T_{b}, T_{c}, T_{d}) decreases upon an increase of at least one of the temperatures Tₐ, T_{b}, T_{c}, T_{d}.

Finally, in the one or more embodiments of a battery module corresponding to FIG. 7C, the average temperature Tₐ, T_{b}, T_{c}, T_{d} of the coatings of each of the respective housings 10a, 10b, 10c, 10d is measured individually. To that end, a first ohmmeter 30a is connected to the points P₁ₐ, P₂ₐ of the first pair of measurement points (P₁ₐ, P₂ₐ) located on the coating of the first housing 10a. A second ohmmeter 30b, a third ohmmeter 30c, and a fourth ohmmeter 30d are connected to the coatings of the second housing 10b, the third housing 10c, and the fourth housing 10d, respectively. This example allows for precise monitoring of the average temperature Tₐ, T_{b}, T_{c}, T_{d} of the coatings of each of the respective housings 10a, 10b, 10c, 10d in comparison to the examples described above with reference to FIGS. 7A and 7B. In one or more embodiments, the manufacture costs of the examples of FIGS. 7A and 7B may be lower in comparison to the example of FIG. 7C, because in the examples of FIGS. 7A and 7B, only a single ohmmeter 30 is used.

Some of the Reference Characters

| | |
|---|---|
| 1: battery cell | 10: housing |
| 10a, 10b, 10c, 10d: housings | 11: case |
| 12: front side | 13: first lateral side |
| 14: second lateral side | 15: bottom side |
| 16: upper side | 20: coating |
| 30: ohmmeter | 30a, 30b, 30c, 30d: ohmmeters |
| 31: wire | 31a, 31b, 31c, 31d: wires (electric conduits) |
| 32: wire | 32a, 32b, 32c, 32d: wires (electric conduits) |
| 40: evaluation unit | 42: signal line |
| 202: stripe of coating | 202a, 202b: stripes of coating |
| 203: stripe of coating | 301, 310, 312, 320: electric conduits (wires) |
| 323, 334, 340: electric conduits (wires) | CL: closing layer |
| 1113, 1213, 1214: vertical edges | OS: outer surface of can |
| IL: insulating layer | P₁ₐ, P₂ₐ: points on coating |
| P₁, P₂: points on coating | P_{1c}, P_{2c}: points on coating |
| P_{1b}, P_{2b}: points on coating | Q₁, Q₂: points on coating |
| P_{1d}, P_{2d}: points on coating | T₁, T₂: cell terminals |
| T_{average}: average temperature | V: venting outlet |
| TL: temperature-sensitive layer | |

x, y, z axes of a Cartesian coordinate system

What is claimed is:

1. A temperature-sensitive housing for a battery cell, the temperature-sensitive housing comprising:
a case having an outer surface; and
a coating at least partially covering the outer surface of the case, and comprising a temperature-sensitive material having a temperature-dependent electrical resistance.

2. The temperature-sensitive housing as claimed in claim 1, wherein the case comprises a substrate material as a substrate for the coating, the substrate material comprising aluminum or an alloy comprising aluminum.

3. The temperature-sensitive housing as claimed in claim 2, wherein the coating comprises an insulating layer comprising an electrically insulating material on the substrate material.

4. The temperature-sensitive housing as claimed in claim 3, wherein the insulating layer comprises an aluminum oxide layer.

5. The temperature-sensitive housing as claimed in claim 3, wherein the insulating layer comprises aluminum oxide and has a thickness of about 0.05 μm or more.

6. The temperature-sensitive housing as claimed in claim 3, wherein the coating comprises a temperature-sensitive layer comprising the temperature-sensitive material.

7. The temperature-sensitive housing as claimed in claim 6, wherein the temperature-sensitive layer directly contacts the insulating layer.

8. The temperature-sensitive housing as claimed in claim 6, wherein the temperature-sensitive layer comprises TiOₓ/Cr₂O₃.

9. The temperature-sensitive housing as claimed in claim 6, wherein the temperature-sensitive layer covers most of the outer surface of the case.

10. The temperature-sensitive housing as claimed in claim 6, wherein the temperature-sensitive layer comprises one or more stripes on the outer surface of the case.

11. A vehicle comprising the temperature-sensitive housing as claimed in claim 1.

12. A battery module comprising the battery cell comprising the temperature-sensitive housing as claimed in claim 1.

13. A vehicle comprising the battery module as claimed in claim 12.

14. The battery module as claimed in claim 12, further comprising:
one or more ohmmeters; and
one or more electric circuits comprising a first measurement terminal and a second measurement terminal,
wherein the temperature-sensitive housing is integrated into at least one of the electric circuits, and
wherein the ohmmeters are configured to measure an electrical resistance between the first measurement terminal and the second measurement terminal of at least one of the electric circuits.

15. A battery system comprising:
the battery module as claimed in claim 14; and
an evaluation unit configured to:
receive signals from the ohmmeters indicating the electrical resistance;
detect a deviance of the signals from a setpoint value assigned to the ohmmeters; and
generate an alert signal upon the deviance exceeding a threshold.

16. A vehicle comprising the battery system as claimed in claim 15.

17. A method for detecting a thermal event occurring in the battery cell equipped with the temperature-sensitive housing as claimed in claim 1, the method comprising:
providing a first electric conduit and a second electric conduit electrically connected at different respective positions to the temperature-sensitive material of the temperature-sensitive housing;
measuring, by ohmmeters, an electrical resistance between the first electric conduit and the second electric conduit;
creating, by the ohmmeters, a signal indicating the electrical resistance;
transferring the signal to an evaluation unit;
evaluating, by the evaluation unit and based on the signal, a deviation of the electrical resistance from a setpoint value; and
generating an alert signal upon the deviation exceeding a threshold.
